(19) United States
(12) Patent Application Publication
(10) Pub. No.: US 2011/0264390 A1
(43) Pub. Date: Oct. 27, 2011

(54) METHOD AND APPARATUS FOR DETERMINING STATE OF CHARGE VALUES FOR AN ELECTRICAL POWER CELL

(76) Inventor: Ayman Shabra, Woburn, MA (US)

(21) Appl. No.: 12/765,843

(22) Filed: Apr. 22, 2010

(51) Int. Cl. G01R 31/36; G01N 27/416

(52) U.S. Cl. 702/63; 324/427

(57) ABSTRACT

A method for determining a state of charge value for an electrical power cell comprises obtaining an indication of a charge level of the electrical power cell, obtaining at least one indication of at least one operating condition for the electrical power cell, and determining an available charge indication value and a potential charge indication value based at least partly on the charge level indication and the at least one operating condition indication.

### FIELD OF THE INVENTION

The field of this invention relates to a method for determining at least one state of charge value for an electrical power cell. The invention is applicable to, but not limited to, an electrical power cell, a battery monitor system, an integrated circuit device, an electronic device and a computer program product therefor.

### BACKGROUND OF THE INVENTION

In the field of battery operated electronic devices it is known to provide a battery State-Of-Charge (SOC) indictor as a part of the user interface of the electronic device. In this manner, a user of the device is provided with an indication of the amount of charge remaining within a battery of the device, and thus an indication of how long the device will remain operational without the battery being re-charged.

Typically, for electronic devices such as mobile telephone handsets and the like, the SOC indicator comprises a visual representation of the available battery capacity and the used battery capacity, for example in a form of a bar chart or the like. This information is typically exhibited on a display or other output device, where the number of highlighted bars represents the available battery capacity, whilst the number of bars not showing or highlighted represent the amount of used battery capacity.

The indication of the available battery capacity is typically calculated from a recent voltage measurement for the battery cell, which is used to determine available battery capacity and/or used battery capacity based on a battery charge profile for that particular battery type. For example, a battery charge profile for that particular battery type may be established using experimental measurements obtained during product development of the battery and/or electronic device that is to use the battery. The battery charge profile may then be used to create a battery charge lookup table or the like for the battery, which can be stored within the electronic device. In this manner, a measured battery voltage may be compared to entries within the lookup table in order to obtain an indication of the available battery capacity and/or used battery capacity.

A problem with traditional battery SOC indicator techniques is that they are prone to non-monotonic behaviour, with the available battery capacity indications prone to fluctuations. Accordingly, from a user perspective traditional battery SOC indicators can be confusing and unreliable.

Thus, a need exists for an improved battery monitoring system for example employed in an integrated circuit or the electronic device comprising the battery and method of operation therefor.

### SUMMARY OF THE INVENTION

Accordingly, the invention seeks to mitigate, alleviate or eliminate one or more of the above mentioned disadvantages singly or in any combination. Aspects of the invention provide an integrated circuit, a method for determining state of charge values for an electrical power cell, an electrical power cell, a battery monitor system, an electronic device and a computer program product therefore, as described in the appended claims.

According to a first aspect of the invention, there is provided a method for determining at least one state of charge value for an electrical power cell. The method comprises obtaining an indication of a charge level of the electrical power cell, obtaining at least one indication of at least one operating condition for the electrical power cell, and determining an available charge indication value and a potential charge indication value based at least partly on the charge level indication and the at least one operating condition indication for the electrical power cell.

Thus, in one embodiment of the invention, operating conditions that may cause variances in an available charge of an electrical power cell, and which typically cause non-monotonic behaviour of traditional state of charge (SOC) indicators, may be taken into consideration when determining the state of charge values. In particular, by determining a potential charge indication value in addition to an available state of charge indication value, such a potential charge indication value may be used to provide, as part of a state of charge indicator, an indication of the potential charge of the electrical power cell as well as the available charge of the electrical power cell. In this manner, a user may be provided with a context in which to interpret any non-monotonic behaviour of the available charge indication. Accordingly, from a user perspective, such non-monotonic behaviour of the available charge of the electrical power cell is less confusing, and a more reliable state of charge indication may be provided to the user.

According to an optional feature of the invention, the at least one indication of at least one operating condition may comprise at least one indication of at least one from a group of: a number of previous charge cycles performed, a monitored temperature of the electrical power cell, and a discharge rate of the electrical power cell.

According to an optional feature of the invention, the method may further comprise calibrating an indication of a charge level of the electrical power cell based on a number of previous charge cycles performed.

According to an optional feature of the invention, the method may further comprise determining an available charge indication value and a potential charge indication value with respect to a discharge capacity of the electrical power cell, based at least partly on the indication of a charge level of the electrical power cell and discharge profile data corresponding to at least one from a group of: a temperature indication and a discharge rate indication.

According to an optional feature of the invention, the indication of a charge level of the electrical power cell may comprise an indication of a terminal voltage of the electrical power cell.

According to an optional feature of the invention, the method may further comprise storing the determined available charge indication value and the potential charge indication value in memory accessible by display logic.

According to a second aspect of the invention, there is provided a battery monitoring system comprising a signal processing module arranged to obtain an indication of a charge level of an electrical power cell, obtain at least one indication of at least one operating condition for the electrical power cell, and determine an available charge indication value and a potential charge indication value based at least partly on the charge level indication and the at least one operating condition indication.

According to a third aspect of the invention, there is provided an electronic device comprising at least one electrical power cell and a signal processing module arranged to obtain an indication of a charge level of an electrical power cell, obtain at least one indication of at least one operating condition for the electrical power cell, and determine an available charge indication value and a potential charge indication value based at least partly on the charge level indication and the at least one operating condition indication.

According to a fourth aspect of the invention, there is provided a computer program product comprising program code for determining state of charge values for an electrical power cell. The computer program product comprises program code operable for obtaining an indication of a charge level of the electrical power cell, obtaining at least one indication of at least one operating condition for the electrical power cell, and determining an available charge indication value and a potential charge indication value based at least partly on the charge level indication and the at least one operating condition indication.

These and other aspects of the invention will be apparent from, and elucidated with reference to, the embodiments described hereinafter.

### BRIEF DESCRIPTION OF THE DRAWINGS

Further details, aspects and embodiments of the invention will be described, by way of example only, with reference to the drawings. Elements in the figures are illustrated for simplicity and clarity and have not necessarily been drawn to scale. Like reference numerals have been included in the respective drawings to ease understanding.

FIG. 1 illustrates an example of a block diagram of a wireless communication unit.

FIG. 2 illustrates an example of a part of a battery monitoring system.

FIG. 3 illustrates a graph of electrical power cell charge level versus discharge capacity, where the graph comprises a series plots corresponding to different temperature ranges.

FIG. 4 illustrates a graph of electrical power cell charge level versus discharge capacity, where the graph comprises a series plots corresponding to different discharge rates.

FIG. 5 illustrates a graph of discharge capacity versus the number of charging cycles.

FIG. 6 illustrates an example of a state of charge indication.

FIG. 7 illustrates an example of a simplified flowchart of a method for determining state of charge values for an electrical power cell.

FIG. 8 illustrates a typical computing system that may be employed to implement signal processing functions in embodiments of the invention.

### DETAILED DESCRIPTION

Examples of the invention will be described in terms of a wireless communication unit. However, it will be appreciated by a skilled artisan that the inventive concept herein described may be embodied in any type of electrical or electronic device comprising an electrical power cell such as a battery cell. In a number of applications, a signal processing module is adapted to perform a method for determining state of charge values for an electrical power cell. The signal processing module is arranged to obtain an indication of a charge level of an electrical power cell and obtain at least one indication of at least one operating condition for the electrical power cell. The signal processing module is further arranged to determine an available charge indication value and a potential charge indication value based at least partly on the charge level indication and the at least one operating condition indication.

In this manner, operating conditions that can cause variances in the available charge of an electrical power cell, and which typically cause non-monotonic behaviour of traditional state of charge (SOC) indicators, may be taken into consideration when determining the state of charge values. In particular, by determining a potential charge indication value in addition to an available state of charge indication value, such a potential charge indication value may be used to provide, as part of a state of charge indicator, an indication of the potential charge of the electrical power cell as well as the available charge of the electrical power cell. In this manner, a user may be provided with a context in which to interpret any non-monotonic behaviour of the available charge indication. Accordingly, from a user perspective, such non-monotonic behaviour of the available charge of the electrical power cell is less confusing, and a more reliable state of charge indication may be provided to the user.

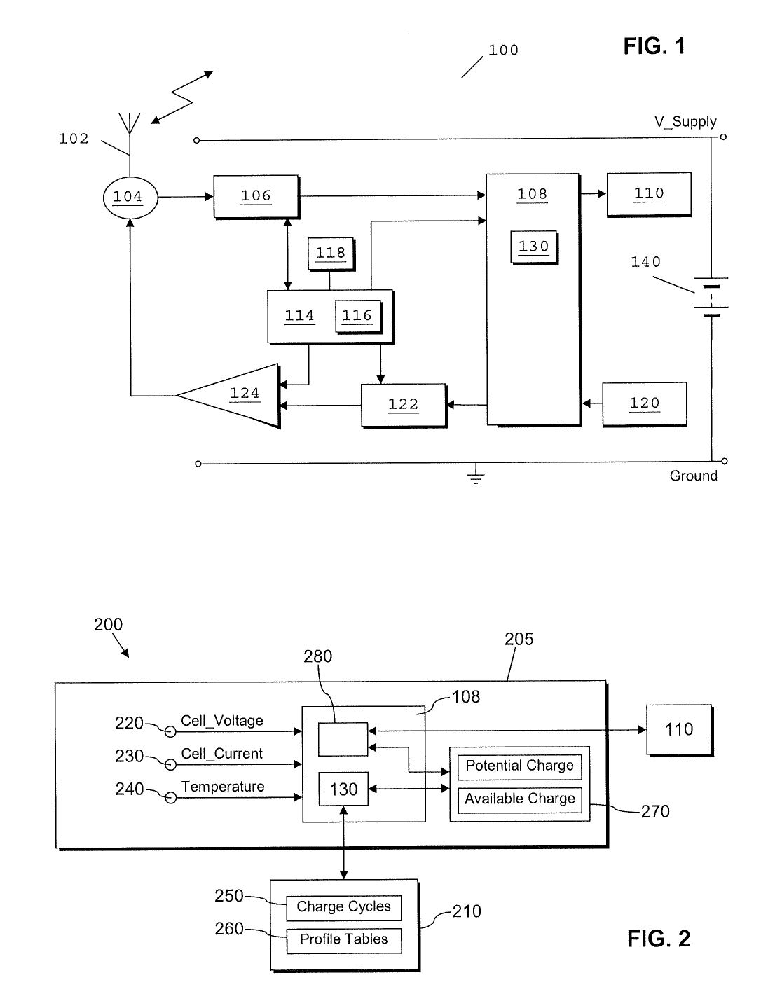

Referring first to FIG. 1, an example of a block diagram of a wireless communication unit 100 (sometimes referred to as a mobile subscriber unit (MS) in the context of cellular communications or a user equipment (UE) in terms of a 3^{rd} generation partnership project (3GPP) communication system) is shown. The wireless communication unit 100 contains an antenna 102 preferably coupled to a duplex filter or antenna switch 104 that provides isolation between receive and transmit chains within the MS 100.

The receiver chain, as known in the art, includes receiver front-end circuitry 106 (effectively providing reception, filtering and intermediate or base-band frequency conversion). The front-end circuitry 106 is serially coupled to a signal processing module 108. An output from the signal processing module 108 is provided to a suitable output device 110, such as a screen or flat panel display. The receiver chain also includes a controller 114 that maintains overall subscriber unit control. The controller 114 is also coupled to the receiver front-end circuitry 106 and the signal processing module 108 (generally realised by a digital signal processor (DSP)). The controller is also coupled to a memory device 116 that selectively stores operating regimes, such as decoding/encoding functions and the like. Furthermore, a timer 118 is operably coupled to the controller 114 to control the timing of operations (transmission or reception of time-dependent signals) within the MS 100.

As regards the transmit chain, this essentially includes an input device 120, such as a keypad, coupled in series through transmitter/modulation circuitry 122 and a power amplifier 124 to the antenna 102. The transmitter/modulation circuitry 122 and the power amplifier 124 are operationally responsive to the controller 114. The signal processor function 108 in the transmit chain may be implemented as distinct from the processor in the receive chain. Alternatively, a single processor 108 may be used to implement processing of both transmit and receive signals, as shown in FIG. 1. Clearly, the various components within the MS 100 can be realised in discrete or integrated component form, with an ultimate structure therefore being merely an application-specific or design selection.

The MS 100 further comprises a power supply 140 arranged to provide a supply voltage to one or more of the components of the MS 100. The power supply 140 typically comprises one or more electrical power cells, for example arranged to convert stored chemical energy into electrical energy. For simplicity the term electrical power cell used herein is intended to incorporate a single electrical power cell and multiple electrical power cells operably coupled together to provide a power supply, such as the power supply 140 of FIG. 1.

In accordance with examples of the invention, the signal processing module 108 is arranged to perform a method for determining state of charge values for the electrical power cell 140. In particular, the signal processing module 108 is arranged to obtain an indication of a charge level of the electrical power cell 140, obtain at least one indication of at least one operating condition for the electrical power cell 140, and determine an available charge indication value and a potential charge indication value based at least partly on the charge level indication and the at least one operating condition indication. For example, the signal processing module 108 may be arranged to execute program code from memory 130 for determining state of charge values for an electrical power cell 140.

Referring now to FIG. 2, there is illustrated an example of a part of a battery monitoring system 200 arranged to perform a method for determining state of charge values for an electrical power cell according to some embodiments of the present invention. In one example, the battery monitoring system 200 forms a part of the electronic device 100 of FIG. 1, and comprises the signal processing module 108, which for the illustrated example forms a part of an integrated circuit device 205.

As previously mentioned, the signal processing module 108 is arranged to obtain an indication of a charge level of the electrical power cell 140, obtain at least one indication of at least one operating condition for the electrical power cell 140, and determine an available charge indication value and a potential charge indication value based at least partly on the charge level indication and the at least one operating condition indication. It will be appreciated that other information may also be used to determine the available charge indication value, such as, by way of example only, an impedance estimate of the electrical power cell 140, an accumulation of the current measurement of the electrical power cell 140, etc. In this manner, one or more operating conditions that may cause variances in the available charge of an electrical power cell, and which thus would cause non-monotonic behaviour of traditional state of charge (SOC) indicators, may be taken into consideration when determining the state of charge values.

The inventor has identified any of at least three primary factors that may cause variances in the available charge of an electrical power cell, namely: temperature of the electrical power cell 140; discharge rate of the electrical power cell 140; and the age of the power cell 140.

It has been found that, for a fully charged Lithium Ion battery, such as is commonly used for providing a power source for battery powered electronic devices, the available charge can reduce by up to 80% when the battery temperature is reduced from 25° C. to, say −20° C. This temperature range is within the normal operating conditions for many battery powered electronic devices.

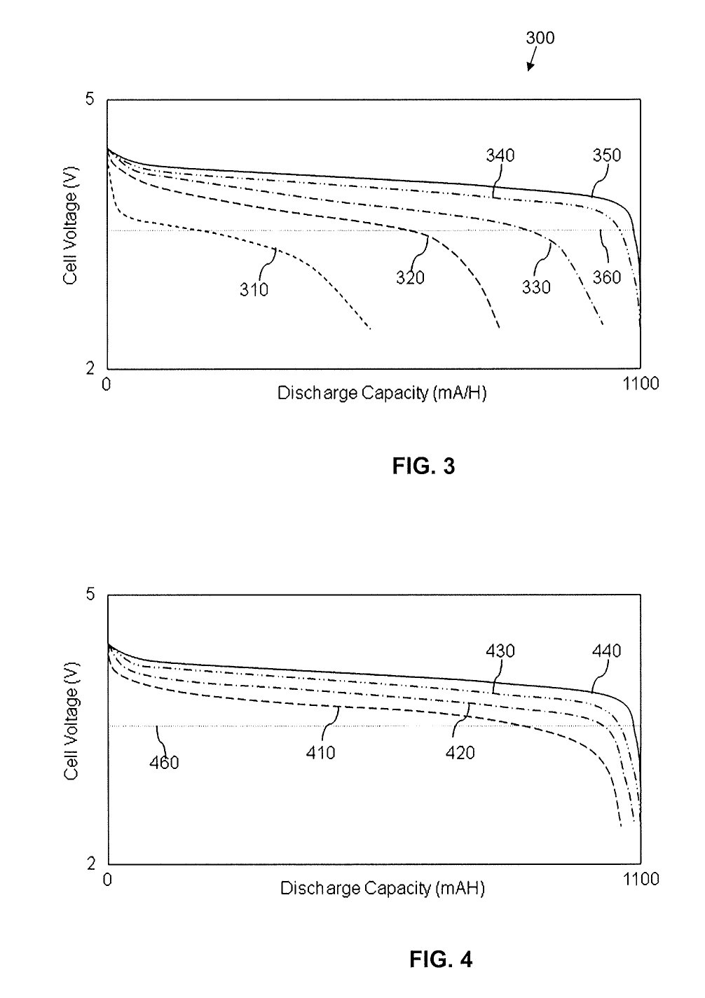

Referring now to FIG. 3, there is illustrated a graph 300 of electrical power cell charge (cell voltage) versus discharge capacity for a typical power cell. The graph 300 comprises a plurality of plots corresponding to different temperatures for the electrical power cell. More specifically the graph 300 comprises a plot 310 corresponding to a temperature of −20° C., a plot 320 corresponding to a temperature of −10° C., a plot 330 corresponding to a temperature of 0° C., a plot 340 corresponding to a temperature of +20° C. and a plot 350 corresponding to a temperature of +40° C. As can be seen, the discharge profile of the electrical power cell varies substantially depending on the temperature of the power cell. Significantly, the discharge capacity of the electrical power cell is typically based on a cell voltage, illustrated at 360, below which the electrical power cell has insufficient voltage to power the electronic device. As can be seen, the variation in the points at which the different temperature plots cross this minimum cell voltage 360 is significant, and has a large impact on the available charge for the electrical power cell. Furthermore, not only does the temperature affect the discharge capacity of the electric power cell, but also the relationship between the cell voltage level and the amount of available charge remaining in the electrical power cell. For example, and as illustrated in the graph 300, for colder temperatures a high cell voltage level tends to have a faster drop off rate relative to the remaining available charge than for warmer temperatures. For warmer temperatures the cell voltage tends to have a faster drop off as it approaches the minimum voltage level 360 relative to the remaining available charge than for colder temperatures. Accordingly, the ability to determine an available charge remaining in the electrical power cell is significantly affected by the temperature of the power cell. In one example embodiment the signal processing module 108 of FIG. 1 and FIG. 2 has been adapted to use this information in determining and potentially providing to a display, a potential charge indication. With regard to the discharge rate, it has been found that a Lithium Ion battery being discharged at its full discharge rate can effectively have an available charge capacity up to 30% lower than a similar battery with a lower discharge rate.

Referring to FIG. 4, there is illustrated a further graph 400 of electrical power cell charge (cell voltage) versus discharge capacity. The graph 400 comprises a plurality of plots corresponding to different discharge rates. More specifically, the graph 400 comprises a plot 410 corresponding to a discharge rate of 2 Amps, a plot 420 corresponding to a discharge rate of 1 Amp, a plot 430 corresponding to a discharge rate of 0.5 Amps and a plot 440 corresponding to a discharge rate of 0.2 Amps. As can be seen, the discharge profile of the electrical power cell varies significantly depending on the discharge rate of the power cell. As can be seen, the variation in the points at which the different discharge rate plots cross a minimum cell voltage 460 (i.e. the cell voltage below which the electrical power cell has insufficient voltage to power the electronic device) is significant, and has a large impact on the available charge for the electrical power cell. Furthermore, the discharge rate of the power cell also affects the relationship between the cell voltage level and the amount of available charge that remains in the electrical power cell, in a similar manner to that described above in relation to temperature.

As a battery/power cell ages, its available charge capacity decreases, and can be reduced by up to 20% over the working lifetime of the battery/power cell.

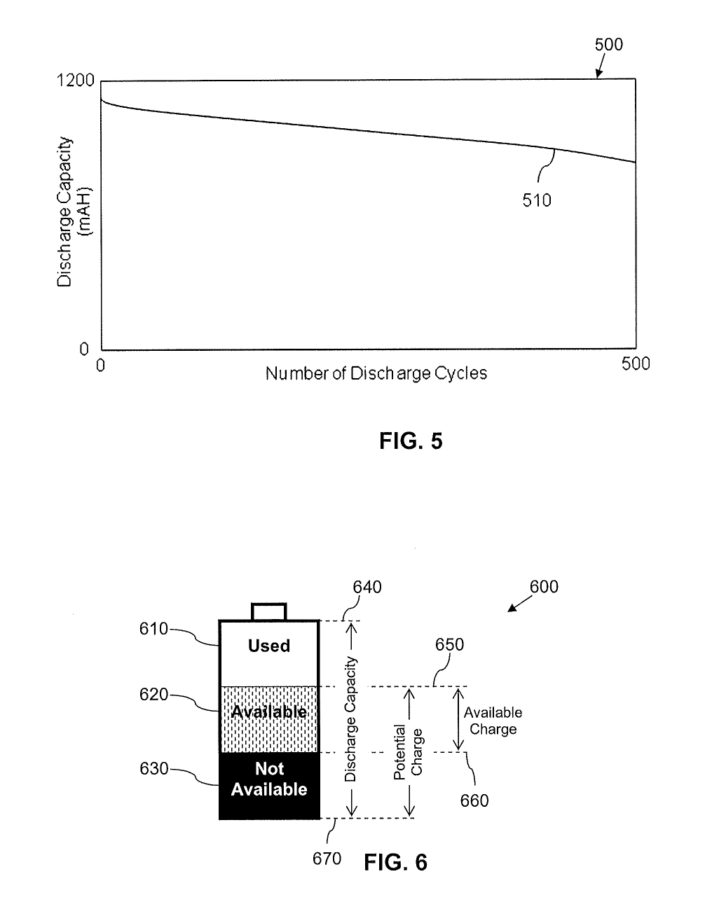

Referring to now FIG. 5, there is illustrated a further graph 500 of discharge capacity versus the number of charging cycles an electrical power cell has been through (which is deemed to be a significant influencing factor of the age of an electrical power cell). As can be seen from the plot 510, the discharge capacity of an electrical power cell decreases at a relatively constant rate with respect to the number of charging cycles the electrical power cell has been through.

Accordingly, and referring back to FIG. 2, the signal processing module 108 may be arranged to execute program code from memory 130 for determining state of charge values for an electrical power cell 140. The signal processing module 108 then determines an available charge indication value and a potential charge indication value based at least partly on an obtained charge level indication for the electrical power cell 140 and on one or more operating condition indications for the electrical power cell 140. The one or more operating condition indications may comprise, in one example, one or more of:

(i) a number of previous charge cycles performed for the electrical power cell 140;

(ii) a temperature of the electrical power cell 140; and

(iii) a discharge rate of the electrical power cell 140.

For example, the signal processing module 108 may be arranged to receive an indication of a charge level of the electrical power cell 140 in a form of a cell voltage level signal illustrated generally at 220. For example, the cell voltage level indication 220 may comprise an indication of a voltage level across the terminals of the electrical power cell 140 (terminal voltage). The signal processing module 108 may further be arranged to retrieve an indication of a number of charge cycles from an area of memory 250, for example within a memory element 210 of the electronic device. Such an indication of a number of charge cycles may be updated by a power management application, or the like (not shown). The signal processing module 108 may then be arranged to calibrate the received charge level indication based on, say, a number of previous charge cycles performed, or a measured discharge capacity during previous discharge cycles. In this manner, the effect on the discharge capacity of the electrical power cell 140 from successive charge cycles may be taken into consideration when determining an available charge value and a potential charge value for the electrical power cell 140. In particular, calibrating the received charge level indication based on a measured discharge capacity during previous discharge cycles enables, for example, a battery change to be compensated for.

Furthermore, the signal processing module 108 may be arranged to determine an available charge indication value and a potential charge indication value for the electrical power cell 140, such as a charge level indication calibrated to take into consideration a number of previous charge cycles, based at least partly on discharge profile data corresponding to one or more operating conditions. For example, the signal processing module 108 may be arranged to receive indications of operating conditions that comprise an indication of a discharge rate for the electrical power cell 140 in a form of a cell current signal 230, and an indication of a temperature for the electrical power cell 140 in a form of a temperature signal 240 from a temperature sensor (not shown). The signal processing module 108 may then retrieve profile data corresponding to the indicated operating conditions from, say, the memory element 210, and determine an available charge indication value and a potential charge indication value from the indication of a charge level of the electrical power cell and the retrieved profile data.

For example, profile data tables 260 that correspond to temperature ranges may be stored within the memory element 210. The signal processing module 108 may accordingly be arranged to retrieve, from the memory element 210, a profile data table 260 relating to a temperature range to which the temperature indication signal 240 corresponds. The signal processing module 108 may then perform a lookup operation for the retrieved profile data table 260 for an available charge indication value and a potential charge indication value based on the (calibrated) charge level indication and discharge rate indication. Alternatively, profile data tables 260 that correspond to discharge rates may be stored within the memory element 210. The signal processing module 108 may accordingly be arranged to retrieve from the memory element 210 a profile data table 260 relating to a discharge rate to which the discharge indication signal 230 corresponds. The signal processing module 108 may then perform a lookup operation for the retrieved profile data table 260 for an available charge indication value and a potential charge indication value based on the (calibrated) charge level indication and temperature indication.

In this manner, the effect of operating conditions, such as temperature and/or discharge rate on the discharge capacity and available charge remaining in the electrical power cell 140, may be taken into consideration when determining the charge indication values.

For the illustrated example, having determined available and potential charge indication values, the signal processing module 108 is further arranged to store the determined available charge indication value and the potential charge indication value in memory such that it is accessible by display logic, such as executable program code 280 running on the signal processing module 108 and arranged to display an indication of the state of charge of the electrical power cell 140 on output device 110. In particular, the signal processing module of FIG. 2 is arranged to store the determined available charge indication value and the potential charge indication value in registers 270. The available charge indication value, and the potential charge indication value, may subsequently be retrieved and displayed within a state of charge indication.

Referring now to FIG. 6, there is illustrated an example of a state of charge indication 600 implemented using an available charge indication value and a potential charge indication value in accordance with some embodiments, such as may be displayed by display logic 280 of FIG. 2. The state of charge indication 600 comprises a graphical representation of the discharge capacity of the electrical power cell 140, illustrated generally at 640 in a form of an outline of a typical battery cell. The state of charge indication 600 further comprises a graphical representation of used charge 610, unused and available charge 620 and unused but not available charge 630, where such unavailable unused charge 630 may be as a result of current operating conditions such as temperature, discharge rate, etc. The combined unused charge comprising both the available charge 620 and unavailable charge 630 may be considered as being the potential charge of the electrical power cell 140. Accordingly, for the example illustrated in FIG. 6, a transition 650 between the available charge 620 and the used charge 610 may be illustrated to be representative of a potential charge indication value determined by the signal processing module 108 with respect to a baseline, illustrated generally at 670.

Additionally, a transition 660 between the available unused charge 620 and the unavailable unused charge 630 may be illustrated to be representative of an available charge indication value determined by the signal processing module 108. For example, the available charge indication value determined by the signal processing module 108 may be representative of the actual available charge of the electrical power cell 140, and as such the transition 660 may be illustrated to be representative of the available charge indication value determined by the signal processing module 108 with respect to the transition 650 between the available charge 620 and the used charge 610, as illustrated in FIG. 6. Alternatively, the available charge indication value determined by the signal processing module 108 may be representative of where the transition 660 from unavailable unused charge 630 to available unused charge 620 is to be, illustrated with respect to the baseline 670.

As the state of charge indication 600 of FIG. 6 illustrates, by enabling the signal processing module 108 to determine a potential charge indication value in addition to an available state of charge indication value, such a potential charge indication value may be used to provide as part of a state of charge indicator an indication of the potential charge of the electrical power cell as well as the available charge of the electrical power cell. In this manner, a user may be provided with a context in which to interpret any non-monotonic behaviour of the available charge indication. Accordingly, from a user perspective, such non-monotonic behaviour of the available charge of the electrical power cell is less confusing, and a more reliable state of charge indication may be provided to the user.

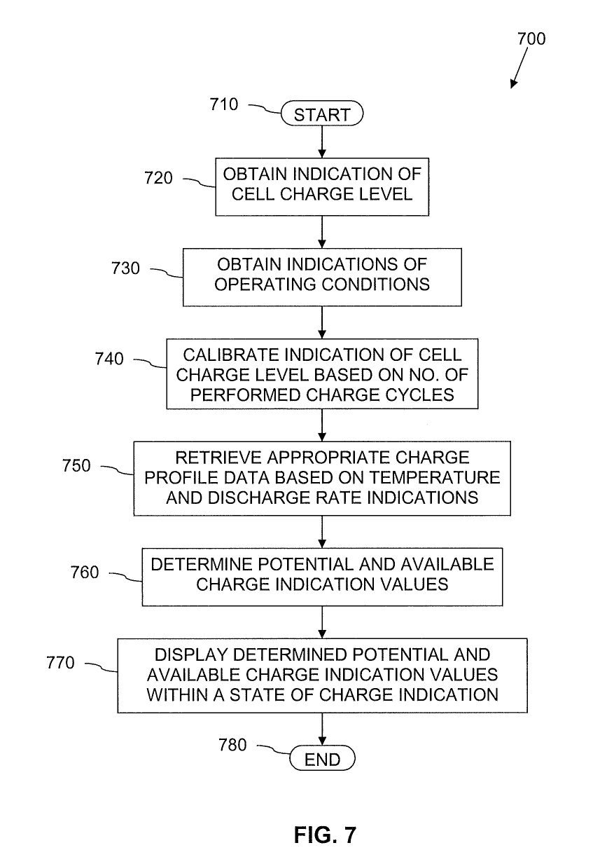

Referring now to FIG. 7, there is illustrated an example of a simplified flowchart 700 of a method for determining state of charge values for an electrical power cell, such as may be performed by the signal processing module 108 of FIG. 2. The method starts at step 710 and moves on to step 720 where an indication of the charge level of a power cell is obtained. Next, at step 730, one or more indications of operating conditions is/are obtained. Specifically for the illustrated example, indications of the number of charge cycles previously performed for the power cell, and/or the temperature of the power cell and/or a discharge rate of the power cell. Accordingly, for the illustrated example the method moves on to step 740 where the indication of the charge level of the power cell is calibrated based on the indication of the number of performed charge cycles. Next, at step 750, appropriate charge profile data is retrieved based on at least one indication of the current operational conditions, which for the illustrated example comprises both temperature and discharge rate indications. A potential charge indication value and an available charge indication value are then determined, at step 760, based at least partly on the (calibrated) charge level indication and the charge profile data corresponding to the indicated operating conditions. The determined charge indication values are then displayed within a state of charge indication 770. For example, the determined charge indication values may be loaded into state of charge registers, from where they may subsequently be retrieved and displayed within a state of charge indication on a display to a user. The method then ends at step 780.

Although examples of the invention have been described with reference to a wireless communication unit 100, it is envisaged that, for alternative applications, the inventive concept may be applied to any electrical or electronic device powered by an electrical power cell, such as a battery cell or the like.

In some examples, some or all of the steps illustrated in the flowchart may be implemented in hardware and/or some or all of the steps illustrated in the flowchart may be implemented in software.

Thus, the hereinbefore examples provide a battery monitoring system for use in an electronic device. In particular, the hereinbefore examples of apparatus and methods are capable of determining state of charge values for an electrical power cell. In one example, a solution is described, whereby a signal processing module is arranged to obtain an indication of a charge level of an electrical power cell, obtain at least one indication of at least one operating condition for the electrical power cell, and determine an available charge indication value and a potential charge indication value based at least partly on the charge level indication and the at least one operating condition indication. In one example a signal processing module arranged to execute program code is used.

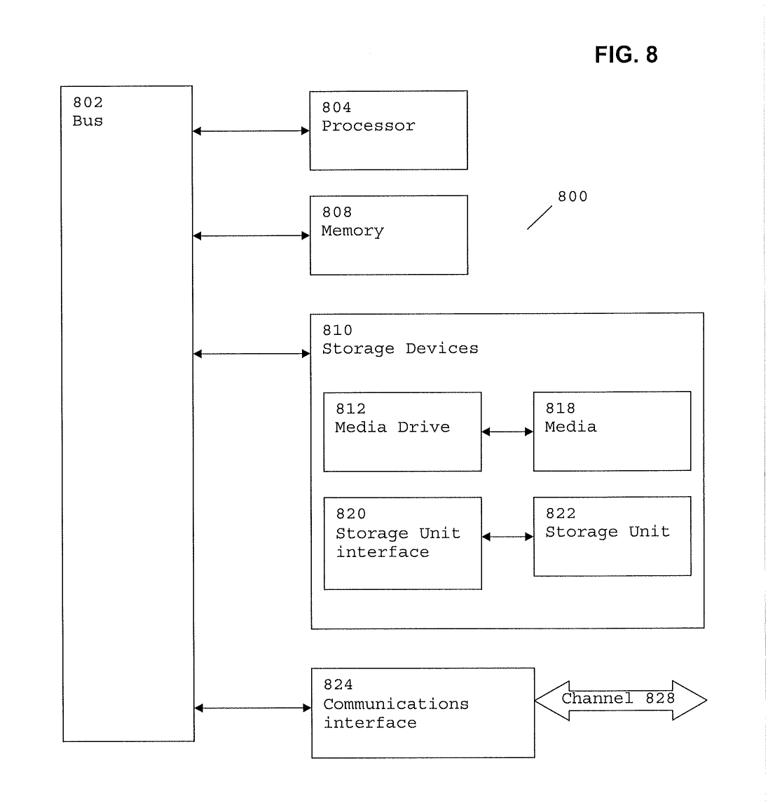

Referring now to FIG. 8, there is illustrated a typical computing system 800 that may be employed to implement signal processing modules in embodiments of the invention. Computing systems of this type may be used in access points and wireless communication units. Those skilled in the relevant art will also recognize how to implement the invention using other computer systems or architectures. Computing system 800 may represent, for example, a desktop, laptop or notebook computer, hand-held computing device (PDA, cell phone, palmtop, etc.), mainframe, server, client, or any other type of special or general purpose computing device as may be desirable or appropriate for a given application or environment. Computing system 800 can include one or more processors, such as a processor 804. Processor 804 can be implemented using a general or special-purpose processing engine such as, for example, a microprocessor, microcontroller or other control module. In this example, processor 804 is connected to a bus 802 or other communications medium.

Computing system 800 can also include a main memory 808, such as random access memory (RAM) or other dynamic memory, for storing information and instructions to be executed by processor 804. Main memory 808 also may be used for storing temporary variables or other intermediate information during execution of instructions to be executed by processor 804. Computing system 800 may likewise include a read only memory (ROM) or other static storage device coupled to bus 802 for storing static information and instructions for processor 804.

The computing system 800 may also include information storage system 810, which may include, for example, a media drive 812 and a removable storage interface 820. The media drive 812 may include a drive or other mechanism to support fixed or removable storage media, such as a hard disk drive, a floppy disk drive, a magnetic tape drive, an optical disk drive, a compact disc (CD) or digital video drive (DVD) read or write drive (R or RW), or other removable or fixed media drive. Storage media 818 may include, for example, a hard disk, floppy disk, magnetic tape, optical disk, CD or DVD, or other fixed or removable medium that is read by and written to by media drive 812. As these examples illustrate, the storage media 818 may include a computer-readable storage medium having particular computer software or data stored therein.

In alternative embodiments, information storage system 810 may include other similar components for allowing computer programs or other instructions or data to be loaded into computing system 800. Such components may include, for example, a removable storage unit 822 and an interface 820, such as a program cartridge and cartridge interface, a removable memory (for example, a flash memory or other removable memory module) and memory slot, and other removable storage units 822 and interfaces 820 that allow software and data to be transferred from the removable storage unit 818 to computing system 800.

Computing system 800 can also include a communications interface 824. Communications interface 824 can be used to allow software and data to be transferred between computing system 800 and external devices. Examples of communications interface 824 can include a modem, a network interface (such as an Ethernet or other NIC card), a communications port (such as for example, a universal serial bus (USB) port), a PCMCIA slot and card, etc. Software and data transferred via communications interface 824 are in the form of signals which can be electronic, electromagnetic, and optical or other signals capable of being received by communications interface 824. These signals are provided to communications interface 824 via a channel 828. This channel 828 may carry signals and may be implemented using a wireless medium, wire or cable, fiber optics, or other communications medium. Some examples of a channel include a phone line, a cellular phone link, an RF link, a network interface, a local or wide area network, and other communications channels.

In this document, the terms ‘computer program product’, ‘computer-readable medium’ and the like may be used generally to refer to media such as, for example, memory 808, storage device 818, or storage unit 822. These and other forms of computer-readable media may store one or more instructions for use by processor 804, to cause the processor to perform specified operations. Such instructions, generally referred to as ‘computer program code’ (which may be grouped in the form of computer programs or other groupings), when executed, enable the computing system 800 to perform functions of embodiments of the present invention. Note that the code may directly cause the processor to perform specified operations, be compiled to do so, and/or be combined with other software, hardware, and/or firmware elements (e.g., libraries for performing standard functions) to do so.

In an embodiment where the elements are implemented using software, the software may be stored in a computer-readable medium and loaded into computing system 800 using, for example, removable storage drive 822, drive 812 or communications interface 824. The control module (in this example, software instructions or computer program code), when executed by the processor 804, causes the processor 804 to perform the functions of the invention as described herein.

In particular, it is envisaged that the aforementioned inventive concept can be applied by a semiconductor manufacturer to any integrated circuit comprising signal processing functionality arranged to perform at least parts of the method herein described. It is further envisaged that, for example, a semiconductor manufacturer may employ the inventive concept in a design of a stand-alone device, such as a digital signal processor (DSP) or microprocessor, or an application-specific integrated circuit (ASIC) and/or any other sub-system element.

It will be appreciated that, for clarity purposes, the above description has described embodiments of the invention with reference to different functional units and signal processors. However, it will be apparent that any suitable distribution of functionality between different functional units or processors may be used without detracting from the invention. For example, functionality illustrated to be performed by single signal processor or functional unit may be performed by a plurality of processors and/or functional units. Hence, references to specific functional units are only to be seen as references to suitable means for providing the described functionality, rather than indicative of a strict logical or physical structure or organization.

Aspects of the invention may be implemented in any suitable form including hardware, software, firmware or any combination of these. The invention may optionally be implemented, at least partly, as computer software running on one or more data processors and/or digital signal processors or configurable module components such as FPGA devices. Thus, the elements and components of an embodiment of the invention may be physically, functionally and logically implemented in any suitable way. Indeed, the functionality may be implemented in a single unit, in a plurality of units or as part of other functional units.

Although the present invention has been described in connection with some embodiments, it is not intended to be limited to the specific form set forth herein. Rather, the scope of the present invention is limited only by the accompanying claims. Additionally, although a feature may appear to be described in connection with particular embodiments, one skilled in the art would recognize that various features of the described embodiments may be combined in accordance with the invention. In the claims, the term ‘comprising’ does not exclude the presence of other elements or steps.

Furthermore, although individually listed, a plurality of means, elements or method steps may be implemented by, for example, a single unit or processor. Additionally, although individual features may be included in different claims, these may possibly be advantageously combined, and the inclusion in different claims does not imply that a combination of features is not feasible and/or advantageous. Also, the inclusion of a feature in one category of claims does not imply a limitation to this category, but rather indicates that the feature is equally applicable to other claim categories, as appropriate.

Furthermore, the order of features in the claims does not imply any specific order in which the features must be performed and in particular the order of individual steps in a method claim does not imply that the steps must be performed in this order. Rather, the steps may be performed in any suitable order. In addition, singular references do not exclude a plurality. Thus, references to ‘a’, ‘an’, ‘first’, ‘second’, etc. do not preclude a plurality.

Thus, an improved battery monitoring system and method of operation therefor have been described, wherein the aforementioned disadvantages with prior art arrangements have been substantially alleviated.

1. A method for determining a state of charge value for an electrical power cell, the method comprising:
obtaining an indication of a charge level of the electrical power cell;
obtaining at least one indication of at least one operating condition for the electrical power cell; and
determining an available charge indication value and a potential charge indication value based at least partly on the charge level indication and the at least one operating condition indication.

2. The method of claim 1 wherein the at least one operating condition comprises at least one from a group consisting of:
a number of previous charge cycles performed by the electrical power cell;
a temperature of the electrical power cell; and
a discharge rate of the electrical power cell.

3. The method of claim 2 further comprising calibrating an indication of a charge level of the electrical power cell based on at least one from a group consisting of:
a number of previous charge cycles performed; and
a measured discharge capacity during previous discharge cycles.

4. The method of claim 2 further comprising determining an available charge indication value and a potential charge indication value with respect to a discharge rate of the electrical power cell based at least partly on the indication of a charge level of the electrical power cell.

5. The method of claim 4 wherein the step of determining is additionally based at least partly on discharge profile data corresponding to at least one from a group consisting of: a temperature indication, a discharge rate indication.

6. The method of claim 1 wherein the indication of a charge level of the electrical power cell comprises an indication of a terminal voltage of the electrical power cell.

7. The method of claim 1 further comprising storing the determined available charge indication value and the potential charge indication value in memory accessible by display logic.

8. The method of claim 1 further comprising displaying representations of the determined available charge indication value and potential charge indication value within a state of charge indication.

9. A battery monitoring system comprising a signal processing module arranged to:
obtain an indication of a charge level of an electrical power cell;
obtain at least one indication of at least one operating condition for the electrical power cell; and
determine an available charge indication value and a potential charge indication value based at least partly on the charge level indication and the at least one operating condition indication.

10. The battery monitoring system of claim 9 further comprising a memory arranged to store the at least one operating condition, wherein the at least one operating condition comprises at least one from a group consisting of:
a number of previous charge cycles performed by the electrical power cell;
a temperature of the electrical power cell; and
a discharge rate of the electrical power cell.

11. The battery monitoring system of claim 10 further comprising logic for calibrating an indication of a charge level of the electrical power cell based on at least one from a group consisting of:
a number of previous charge cycles performed; and
a measured discharge capacity during previous discharge cycles.

12. The battery monitoring system of claim 10 wherein the signal processing module determines an available charge indication value and a potential charge indication value with respect to a discharge rate of the electrical power cell based at least partly on the indication of a charge level of the electrical power cell.

13. The battery monitoring system of claim 12 wherein signal processing module determines an available charge indication value and a potential charge indication value additionally based at least partly on discharge profile data corresponding to at least one of: a temperature indication and a discharge rate indication.

14. The battery monitoring system of claim 9 wherein the indication of a charge level of the electrical power cell comprises an indication of a terminal voltage of the electrical power cell.

15. The battery monitoring system of claim 9 further comprising a memory arranged to store the determined available charge indication value and the potential charge indication value.

16. The battery monitoring system of claim 9 wherein the signal processing module is further arranged to display representations of the determined available charge indication value and potential charge indication value within a state of charge indication.

17. An electronic device comprising at least one electrical power cell and a signal processing module arranged to:
obtain an indication of a charge level of the at least one electrical power cell;
obtain at least one indication of at least one operating condition for the at least one electrical power cell; and
determine an available charge indication value and a potential charge indication value based at least partly on the charge level indication and the at least one operating condition indication.

18. The electronic device of claim 17 further comprising a display operably coupled to the signal processing module and arranged to display the available charge indication value and a potential charge indication value.

19. A computer program product comprising executable program code for determining a state of charge value for an electrical power cell, the executable program code operable for:
obtaining an indication of a charge level of the electrical power cell;
obtaining at least one indication of at least one operating condition for the electrical power cell; and
determining an available charge indication value and a potential charge indication value based at least partly on the charge level indication and the at least one operating condition indication.

20. The computer program product of claim 19 wherein the computer readable storage medium comprises at least one of a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory.
